(19) United States
(12) Patent Application Publication
(10) Pub. No.: US 2022/0391550 A1
(43) Pub. Date: Dec. 8, 2022

(54) WEATHER STATION LOCATION SELECTION USING ITERATION WITH FRACTALS

(71) Applicant: INTERNATIONAL BUSINESS MACHINES CORPORATION, Armonk, NY (US)

(72) Inventors: Clement Decrop, Arlington, VA (US); Martin G. Keen, Cary, NC (US); Zachary A. Silverstein, Austin, TX (US); Jeremy R. Fox, Georgetown, TX (US)

(21) Appl. No.: 17/340,212

(22) Filed: Jun. 7, 2021

(51) Int. Cl. G06F 30/13; G06K 9/62; G06N 3/08; G01W 1/00

(52) U.S. Cl. CPC G06F 30/13; G06K 9/6211; G06N 3/08; G01W 1/00

(57) ABSTRACT

A method, computer system, and a computer program product for weather station placement design are provided. Weather data measured at weather stations, current location data regarding current locations of the respective weather stations, and weather forecast data generated by a weather forecast model are received. Forecast performance by the weather forecast model is determined by comparing the weather data to the weather forecast data and so that first weather stations where the weather forecast model had best forecast performance are identified. A weather forecast performance map is generated based on the identified first weather stations. Fractals are generated. The fractals are iteratively matched to the weather forecast performance map to identify a first fractal that most closely matches a layout of the current locations of the first weather stations. A first fractal map that includes the first fractal overlaid on the weather forecast performance map is presented.

### BACKGROUND

The present invention relates generally to weather measurement and computer-based weather prediction, and more particularly to machine learning-based location selection of weather stations which measure weather variables.

### SUMMARY

According to one exemplary embodiment, a method for weather station placement design is provided. Weather data measured at weather stations, current location data regarding current locations of the respective weather stations, and weather forecast data generated by a weather forecast model are received. Forecast performance by the weather forecast model is determined by comparing the weather data to the weather forecast data and so that first weather stations where the weather forecast model had best forecast performance are identified. A weather forecast performance map is generated based on the identified first weather stations. Fractals are generated. The fractals are iteratively matched to the weather forecast performance map to identify a first fractal of the fractals that most closely matches a layout of the current locations of the first weather stations. A first fractal map that includes the first fractal overlaid is presented. A computer system and computer program product corresponding to the above method are also disclosed herein.

### BRIEF DESCRIPTION OF THE DRAWINGS

These and other objects, features, and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates a networked computer environment according to at least one embodiment;

FIG. 2 is an operational flowchart illustrating a weather station location selection process according to at least one embodiment;

FIG. 3A shows a fractal map that may be generated by the weather station location selection process according to at least one embodiment;

FIG. 3B shows a fractal map that may be generated by the weather station location selection process according to another embodiment;

FIG. 4 shows a fractal map that may be generated by the weather station location selection process according to another embodiment;

FIG. 5 shows an example of a fractal configuration that may be produced according to one embodiment;

FIG. 6 is a block diagram of internal and external components of computers, phones, and servers depicted in FIG. 1 according to at least one embodiment;

FIG. 7 is a block diagram of an illustrative cloud computing environment including the computer system depicted in FIG. 1, in accordance with an embodiment of the present disclosure; and

FIG. 8 is a block diagram of functional layers of the illustrative cloud computing environment of FIG. 7, in accordance with an embodiment of the present disclosure.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

The following described exemplary embodiments provide a system, method, and computer program product for weather station location selection which incorporate fractal map generation and overlaying of fractals onto weather station maps to optimize placement of weather stations for enhanced measurement of weather variables which may lead to improved weather prediction. The present embodiments help implement fractal maps with machine learning (ML) to determine best placement and arrangement of weather stations. The present embodiments may enhance weather prediction on an aggregate level and on a partial level, may lead to the optimization of supply chains, may lead to improvement of crop growing, and may lead to saving lives and money. The present embodiments help enhance machine learning libraries by allowing machine learning to be harnessed to dynamically and repeatedly determine optimal positioning for weather stations.

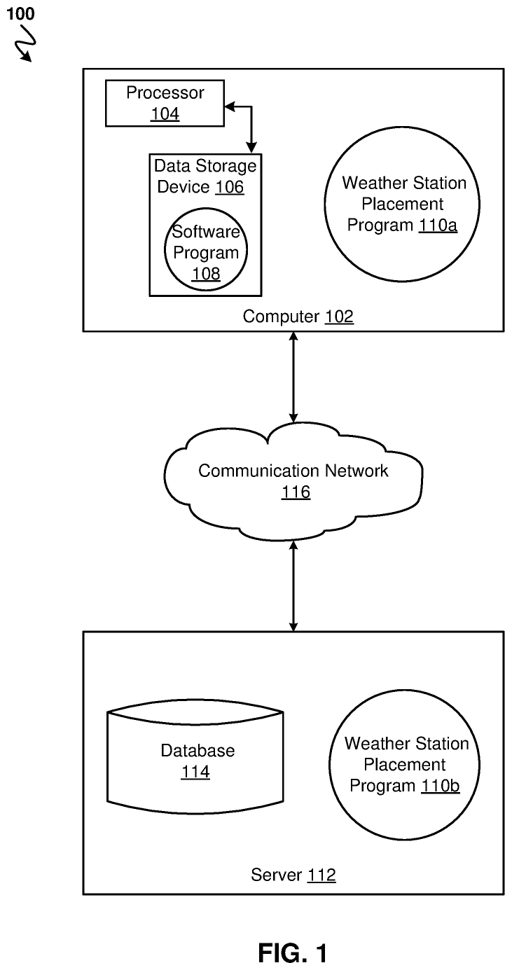

Referring to FIG. 1, an exemplary networked computer environment 100 in accordance with one embodiment is depicted. The networked computer environment 100 may include a computer 102 with a processor 104 and a data storage device 106 that is enabled to run a software program 108 and a weather station placement program 110a. The networked computer environment 100 may also include a server 112 that is a computer and that is enabled to run a weather station placement program 110b that may interact with a database 114 and a communication network 116. The networked computer environment 100 may include a plurality of computers 102 and servers 112, although only one computer 102 and one server 112 are shown in FIG. 1. The communication network 116 allowing communication between the computer 102 and the server 112 may include various types of communication networks, such as the Internet, a wide area network (WAN), a local area network (LAN), a telecommunication network, a wireless network, a public switched telephone network (PTSN) and/or a satellite network. It should be appreciated that FIG. 1 provides only an illustration of one implementation and does not imply any limitations with regard to the environments in which different embodiments may be implemented. Many modifications to the depicted environments may be made based on design and implementation requirements.

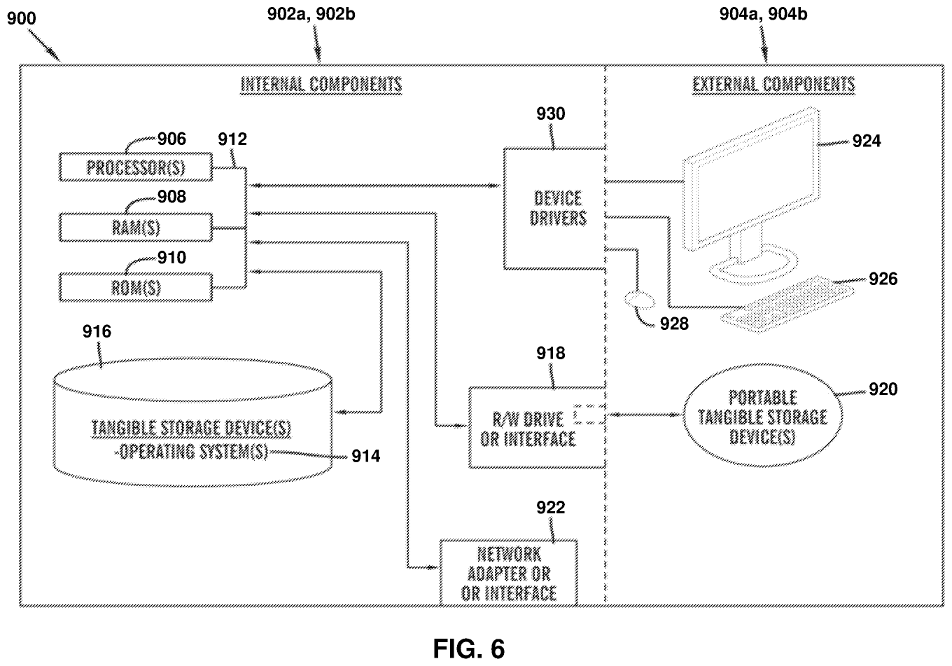

The client computer 102 may communicate with the server 112 via the communication network 116. The communication network 116 may include connections, such as wire, wireless communication links, or fiber optic cables. As will be discussed with reference to FIG. 6, server 112 may include internal components 902a and external components 904a, respectively, and client computer 102 may include internal components 902b and external components 904b, respectively. Server 112 may also operate in a cloud computing service model, such as Software as a Service (SaaS), Platform as a Service (PaaS), or Infrastructure as a Service (IaaS). Server 112 may also be located in a cloud computing deployment model, such as a private cloud, community cloud, public cloud, or hybrid cloud. Client computer 102 may be, for example, a mobile device, a telephone, a personal digital assistant, a netbook, a laptop computer, a tablet computer, a desktop computer, or any type of computing devices capable of running a program, accessing a network, and accessing a database 114 in a server 112 that is remotely located with respect to the client computer 102. The client computer 102 will typically be mobile and include a display screen and a camera. According to various implementations of the present embodiment, the weather station placement program 110a, 110b may interact with a database 114 that may be embedded in various storage devices, such as, but not limited to a computer/mobile device 102, a networked server 112, or a cloud storage service.

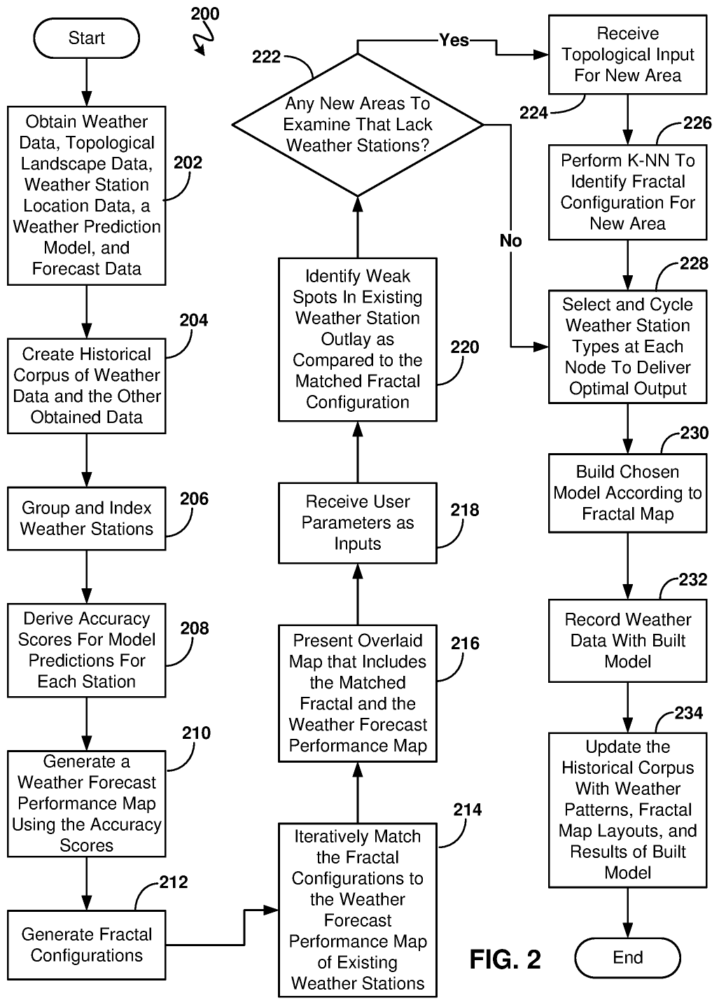

Referring now to FIG. 2, an operational flowchart depicts a weather station placement process 200 that may, according to at least one embodiment, be performed by the weather station placement program 110a, 110b. The weather station placement program 110a, 110b may include various modules, user interfaces, and services and may use data storage to perform the weather station placement process 200. A computer system with the weather station placement program 110a, 110b operates as a special purpose computer system in which the weather station placement program 110a, 110b assists in automatically suggesting enhancements for placement of weather stations in weather station systems in order to improve weather variable measurement and weather forecasting. In particular, the weather station placement program 110a, 110b transforms a computer system into a special purpose computer system as compared to currently available general computer systems that do not have the weather station placement program 110a, 110b.

In a step 202, weather data, topological landscape data, weather station location data, a weather prediction model, and forecast data are obtained. Weather data, topological landscape data, and weather station location data may be obtained by receiving a digital file, whereby the receiving of the digital file may occur via the communication network 116 that is shown in FIG. 1. The receiving may occur via the weather station placement program 110a receiving an uploaded file at the computer 102 or via the weather station placement program 110b at the server 112 receiving a digital file that was transmitted via the communication network 116, e.g., that was transmitted from the computer 102 through the communication network 116 to the server 112.

The weather stations involved in step 202 and in other steps of the weather station placement process 200 may be facilities located on land and/or on sea and that have instruments and equipment for measuring environmental and/or atmospheric conditions to provide information for weather forecasts and to study the weather and climate. The location data may relate to current locations of the weather stations, so that the location data may in at least some embodiments include current location data of the weather stations and in some embodiments may include past location data of the weather stations that may or may not be the same as the current location data.

The instruments and equipment of the weather stations may be configured to measure temperature, atmospheric pressure, humidity, wind speed, wind direction, precipitation amounts, etc. Wind measurements may be taken while reducing or eliminating wind obstructions. Temperature and humidity measurements may be taken while avoiding direct solar radiation or insolation. The instruments and equipment may be configured to measure air quality, desert dust concentration, ozone amounts, swell size of the sea, sea temperature, soil moisture, evapotranspiration, leaf wetness, surface moisture, air turbulence, the soaring index, air vorticity, cloud cover, snow amounts, ice amounts, hail amounts, rain amounts, time of sun rise, time of sun set, etc.

The weather station location data that is obtained may include specific coordinates, such as latitude, longitude, altitude, global positioning system coordinates, etc., of each of the weather stations. Each weather station may be indexed in order to facilitate identification of the weather stations and to facilitate matching of weather data and weather station. Various weather stations in a system may all gather the same weather data, may gather some of the same weather data, or may gather completely different weather data. Various weather stations gathering different data may be a result of the weather stations having different equipment.

The weather forecast data that is obtained may include the time of sunrise and sunset, the temperature throughout the day, the humidity, the chance of rain, snow, hail, sleet, or other moisture and predictions of other weather variables. The weather forecast data may be associated with a particular region and, thereby, with one or more weather stations. The weather forecast data may be obtained with time length indexing in which a weather forecast is made for a specific time length into the future ahead of the time of forecasting. The time length indexing may be divided into various time length prediction categories such as immediate, e.g., less than 1 hour into the future; short term, e.g., less than 24 hours into the future, medium term, e.g., one or more months into the future, and long term, e.g., a year or more into the future. The weather forecast data may be obtained from an application programming interface (API) that may access data from a weather predicting entity such as The Weather Channel®. The Weather Channel® is a registered trademark of TWC Product and Technology, LLC or of International Business Machines Corporation. The weather forecast data may be obtained from a website or database operated by the weather predicting entity such as The Weather Channel®.

The one or more weather prediction models that are obtained in step 202 may be the models that generate the forecast data that is obtained in step 202. The obtaining of one or more weather prediction models may include gaining access to one or more weather prediction models that are stored on remote servers. This access may be gained by the computer 102 and/or the server 112 gaining access via the communication network 116 to one or more remote servers that store the one or more weather prediction models.

The one or more weather forecast models may include numerical weather prediction models and/or deep learning machine learning models/artificial intelligence.

Numerical weather prediction models may include complex sets of mathematical equations based on the physics related to air movement and heat/moisture exchange throughout the atmosphere. The numerical weather prediction models may include approximations unique to each model and may have a unique mode of assimilating weather observations. A numerical weather prediction model may use broad-based initial weather conditions for calculations because future weather in some locations is affected by current weather in other locations. Weather conditions from many or multiple locations, even worldwide conditions, may be entered into the model as initial conditions.

Deep learning machine learning models which may be considered artificial intelligence have also been used for weather forecasting. A deep learning model may include a neural network, a convolutional neural network (CNN), a recurrent neural network (RNN), long short-term memory (LSTM) nodes, gated recurrent units (GRU), ConvLSTM networks which include a combination of a normal CNN with LSTM, variational auto-encoders (VAE), generative adversarial networks (GAN), combinations of VAE and CNN layers, combinations of GAN and CNN layers, multi-layer perceptron architectures, boosted decision trees, dynamic Gaussian Process models, deep belief networks that include restricted Boltzman machines, stochastic adversarial video predictions, and other systems. Deep learning models may be trained in a supervised manner with the labeling of data or in an unsupervised manner without the labeling of data.

In at least some embodiments, the data received for step 202 may be obtained with application programming interface (API) access to web systems that have gathered some or all of this data. For example, in at least some embodiments, step 202 may be performed by the weather station placement program 110a, 110b using API access via the communication network 16 with The Weather Channel®, e.g., via a website or database operated by The Weather Channel®.

Topological landscape data may indicate surface character of the geographic region in which a weather station is disposed. This topological landscape data may indicate whether the surface in the vicinity is mountainous, hilly, filled with valleys, flat, etc. In some instances, weather measurements in a mountainous area may change substantially with a small change in GPS coordinates, for example for two spots on opposite sides of a peak or two spots at different elevations along a steep cliff. Such an environment may have different micro-environments for weather measurement. In contrast, in some areas all micro-areas within one region would share weather characteristics. Weather stations may be equipped to measure or determine topological land characteristics and elevation at their location and near surrounding areas. Topological maps already generated may be accessed to gather topological landscape data.

The weather data that is obtained may be from past times and time periods that include past days, weeks, months, and years. The weather data may have been gathered on a continual basis, on an hourly basis, and/or on a daily basis.

In a step 204 of the weather station placement process 200, a historical corpus of weather data and the other obtained data is created. This weather data and the other obtained data may be the data that was obtained in step 202. The other obtained data may include topological landscape data and weather station location data that was obtained in step 202. The historical corpus may be stored in the database 114 of the server 112 and/or in the data storage device 106 of the computer 102. Additionally and/or alternatively, all or some of the historical corpus may be stored in some other remote server that is accessed by the server 112 and/or by the computer 102 via the communication network 116. The historical corpus may include the data as unstructured data or as structured data or as a combination of those two types, although weather data is typically established in a format suitable for structured data.

In a step 206 of the weather station placement process 200, weather stations are grouped and indexed. The weather stations that are grouped and indexed in step 206 may be those weather stations whose location data was obtained in step 202.

The grouping of the weather stations may occur via performance of a k-means algorithm which may generate “k” clusters of the weather stations. The k-means algorithm may group the weather stations according to which weather variables they measure. A cluster of weather stations may be those which measure all or more of the same weather variables. The k-means algorithm may additionally or alternatively group the weather stations according to similarity in the raw measurement data that is measured. Therefore, weather stations in locations where the weather is similar may be clustered together. Performance of the k-means algorithm may help determine how many different generally types of weather stations are present in a data set. The k-means clustering may include assigning data points, each representing a weather station, to a cluster in a way so that the sum of the squared distance between the data points and the cluster centroid is at the minimum. This calculation with various centroids may be performed iteratively to determine the location of the centroids. The less variation that is present within the clusters means the more homogeneous or similar the data points are within the same cluster. The k-means clusters and/or the groups of weather stations may be displayed on the display screen 924 shown in FIG. 6 or on the screen of the computer 102.

The indexing of the weather stations may include entering and storing an identifier for each weather station into a list or table. The list or table may associate the location of a respective weather station with the identifier of the respective weather station. The weather stations in the index may be grouped according to clusters or groups that are generated in performing a k-means algorithm for the weather stations. The weather stations may also be indexed according to time length and years of historical weather data for which they have measured and gathered data and for which the weather forecast model made predictions for the weather at their location.

In a step 208 of the weather station placement process 200, accuracy scores for model predictions for each weather station are derived. The accuracy scores may measure the ability of the weather forecast model to forecast the weather at locations that correspond to particular weather stations of the weather stations whose location data was obtained in step 202. An accuracy score may be generated regarding weather forecast model predictive success around each weather station. The accuracy score may be altered based on length into the future of the forecast. For example, weather forecast models generally predict shorter-term times into the future with more accuracy than for longer-term times. It is easier to predict the weather of tomorrow than it is to predict the weather of one week or one month into the future. The present weather may help guide a more accurate prediction of the weather of the following day as opposed to weather in a week or a month from the present time. A higher score for a short-term weather prediction may require greater prediction accuracy than a higher score for a longer-term weather prediction would require. A list of the weather prediction accuracy scores may be displayed on the display screen 924 shown in FIG. 6 or on the screen of the computer 102.

Various statistical analyses may be performed on the forecast data that was obtained in step 202 as compared to the weather data that was maintained in step 202 in order to determine prediction accuracy. The weather data may relate to weather as reflected in the weather variable measurements that were taken at the various weather stations whose location data was obtained in step 202. For a model that perfectly forecast the weather, the difference between the forecast values and the measured values for a location/station would be zero. Various procedures may be performed on the difference between the predicted and actual values in order to quantify the prediction accuracy.

In at least some embodiments, the weather prediction accuracy score is calculated by using one or more of the mean absolute error, the mean squared error, the root mean squared error, the relative absolute error, the relative squared error, and r-squared (R²). The measured weather data and the weather forecast data may be used as input variables for one or more of these calculations.

Step 208 may also include performing a K-folds cross validation with the weather data in order to calculate the accuracy score. The K-folds cross validation may include inputting a new set of weather data into the weather forecast model, whereby the new set of weather data was not previously used for training the weather forecast model. The K-folds cross validation may include separating a sample of data into complementary subsets, performing the analysis on one subset called the training set, and validating the analysis on the other subsets called the validation set or testing set. To reduce variability, multiple cycles of cross-validation may be performed using different partitions. The validation results may be combined and averaged over the multiple cycles to give an estimate of the predictive performance that is being achieved by the model. The weather data input for K-folds cross validation may include a collection of measured weather data, with measured weather data for earlier time periods being used as inputs to test if the weather forecast model can predict weather data that was measured in later time periods in the weather data set.

Using the weather prediction accuracy score that has been derived in step 208, in some embodiments the weather station placement program 110a, 110b builds a profile that indicates around or at which weather stations the weather forecast model has predicted the weather most accurately and reliably.

In addition, the weather station placement program 110a, 110b may also perform a k-means algorithm which may generate “k” clusters of the weather stations based on weather prediction accuracy that the weather forecast model has achieved for the locations of the weather stations. The k-means algorithm may group the weather stations according to accuracy level of the predictions. The k-means clustering may include assigning data points, each representing a weather station, to a cluster in a way so that the sum of the squared distance between the data points and the cluster centroid is at the minimum. This calculation with various centroids may be performed iteratively to determine the location of the centroids. Data points for the weather stations in the areas for which the weather was predicted most accurately may all be grouped in a first cluster of the k-means clusters. Data points for the weather stations in the areas for which the weather was predicted least accurately may all be grouped in another cluster of the k-means clusters. The k-means clusters may be displayed on the display screen 924 shown in FIG. 6 or on the screen of the computer 102.

For embodiments where the weather forecast model is or includes a linear regression model, linear regression techniques may be performed as a part of step 208 using the weather data. These linear regression techniques may help refine and improve the weather prediction process and capability of the weather forecast model. The linear regression may include determining a conditional probability distribution of a weather response given values of predictors such as weather at previous times and weather at previous times in adjacent or distant locations. The linear regression techniques may include calculating one or more of the mean absolute error, the mean squared error, the root mean squared error, the relative absolute error, the relative squared error, and r-squared (R²) of the weather data. The linear regression techniques may be used to refine the weather forecast model or to train a new model using the weather data as training data.

In a step 210 of the weather station placement process 200, a weather forecast performance map is generated using the accuracy scores. In at least some embodiments, the weather forecast performance map may include a heat map. The weather station placement program 110a, 110b may generate the weather forecast performance map, e.g., the heat map, based on the error/accuracy scores that are derived in step 208. The weather forecast performance map may include the weather stations that are disposed corresponding to their geographical placements on the earth.

The heat map may include indicators, e.g., visual indicators such as color indicators, that correspond to accuracy levels for weather prediction that was performed by the weather forecast model. The heat map may divide the areas of the map into at least two accuracy levels, e.g., three, four, or five accuracy levels. For example, areas with highest performance may be indicated with a first color, e.g., red, on the map. Areas with average performance may be indicated with a second color, e.g., blue, on the map. Areas with the lowest performance may be indicated with a third color, e.g., yellow, on the map. This generation of the weather forecast performance map may help a viewer more quickly understand for which geographical areas the weather forecast model is predicting well and for which geographical areas the weather forecast model is predicting poorly. By using these accuracy scores as the basis for the weather forecast performance map, in at least some embodiments the determining of the forecast performance and generation of this weather forecast performance map may be based on identified first weather stations at which the forecast model had the best prediction performance.

The weather forecast performance map may in some embodiments separate the accuracy levels or may include all accuracy levels and provide distinction indications for the various accuracy levels, e.g., by using a different color for each of the various accuracy levels. In some embodiments, a first weather forecast performance map may include all points representing weather stations in areas where the highest accuracy level in predictions were achieved. The weather stations represented by these points may be referred to as first weather stations. A second weather forecast performance map may include all points representing weather stations in areas where a medium accuracy level in predictions were achieved. A third weather forecast performance map may include all points representing weather stations in areas where the lowest accuracy level in predictions were achieved. Separating the various accuracy levels into different maps may help simplify subsequent overlaying with a fractal and node to weather station point measurement that will be explained subsequently. The weather forecast performance map may show the layout of the current locations of first weather stations, namely those weather stations at which the weather forecast model has been achieving the best performance.

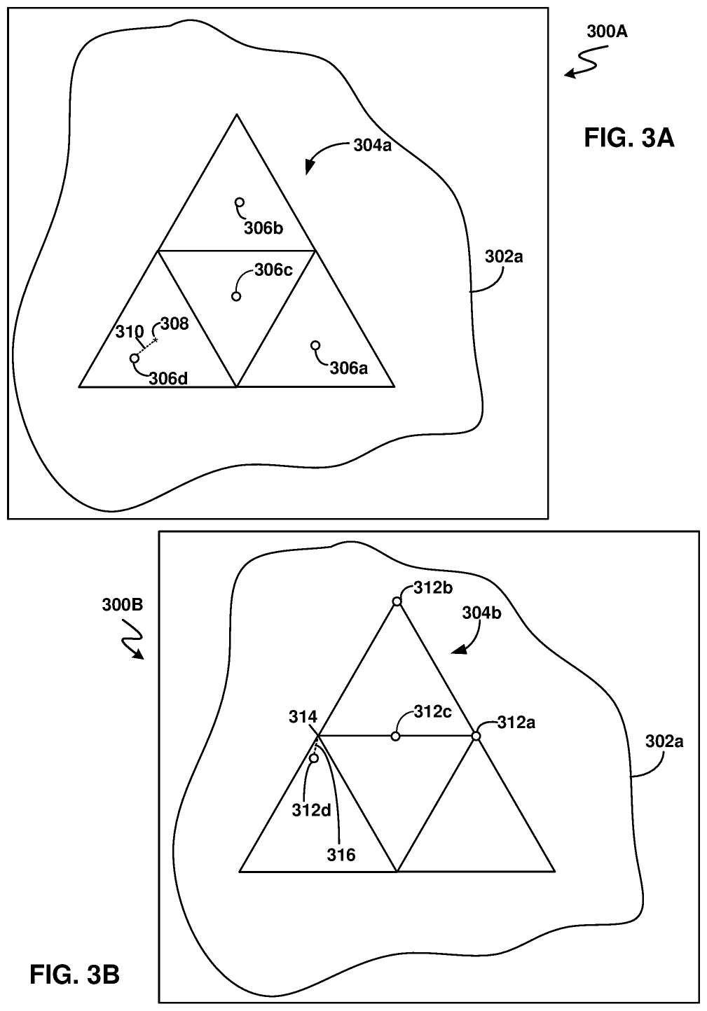

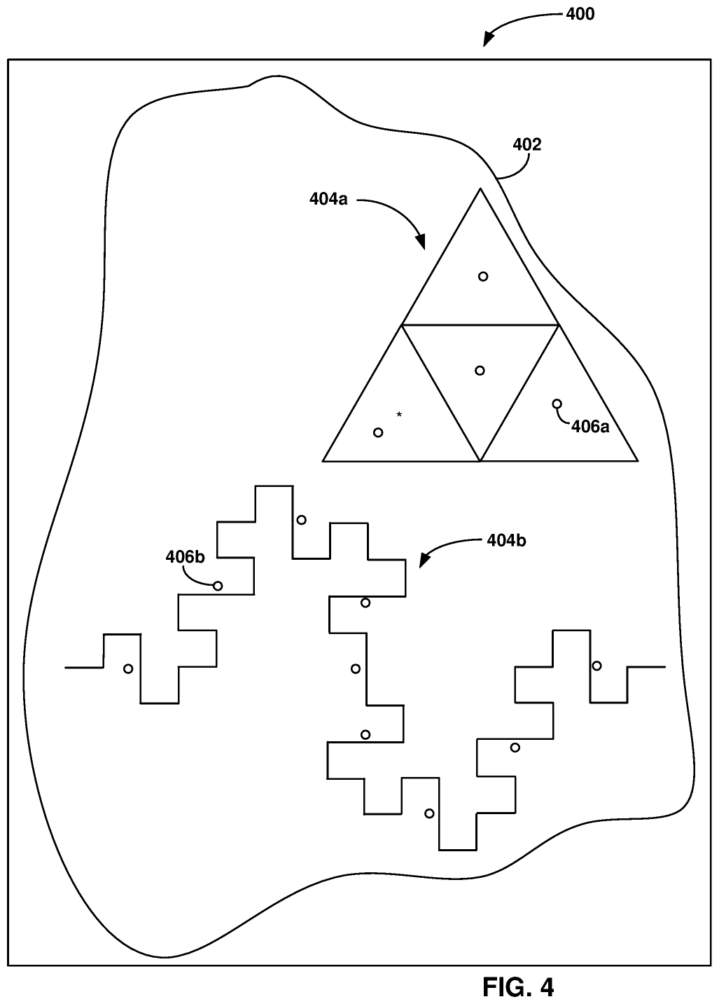

FIGS. 3A, 3B, and 4 show examples of maps that have points, in these cases empty circles, representing positions of weather stations at which a weather forecast model had the highest accuracy level for its weather predictions. The weather stations represented by these points may be referred to as first weather stations. In FIG. 3A, the first, second, third, and fourth points 306a, 306b, 306c, and 306d represent weather stations where a weather forecast model had the highest accuracy level for its weather predictions. In FIG. 3B, the fifth, sixth, seventh, and eighth points 312a, 312b, 312c, and 312d represent weather stations where a weather forecast model had the highest accuracy level for its weather predictions. In FIG. 4, the points (empty circles) represent weather stations where a weather forecast model had the highest accuracy level for its weather predictions, with two of these points being labeled, namely the first northern point 406a and the first southern point 406b.

The heat map in some embodiments may also include topological features of the land such as elevation, so that correlations between accurate weather prediction by the weather forecast model and topological properties of the land may be recognized. In some embodiments, the weather forecast performance map with topological features may indicate a terrain type for the land, e.g., whether the land is a forest region, a mountainous region, a desert region, a swamp region, a plains region, a marsh region, a hill region, a grasslands region, a glacier region, a canyon region, an oasis region, a river region, an ocean region, a tundra region, a valley region, a volcano region, etc. The weather forecast performance map, e.g., the heat map, may be displayed on the display screen 924 shown in FIG. 6 or on a display screen of the computer 102.

The weather forecast performance map may also have a future time component for the predictions that were measured. In other words, for a certain region the weather forecast model may have a higher level of performance compared to other regions for 1-day-in-advance predictions as opposed to 1-week-in-advance predictions. Thus, for weather stations in one region different weather forecast performance maps may be generated based on the time component of length into the future of the prediction. A weather forecast performance map may for example be generated for prediction accuracies 1 hour into the future, less than 24 hours into the future, one or more months into the future, and one or more years into the future.

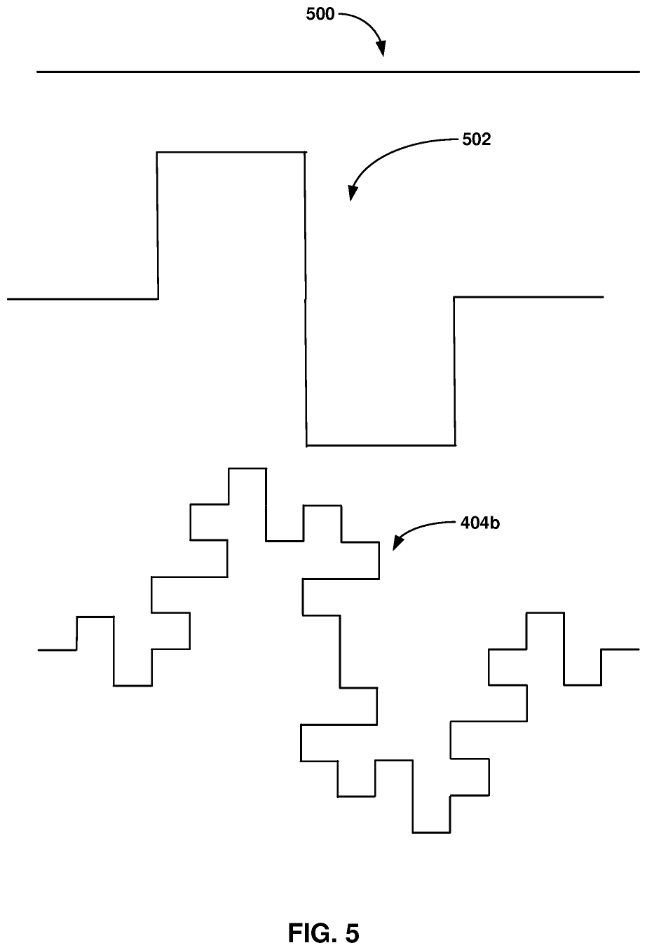

In a step 212 of the weather station placement process 200, fractal configurations are generated. A fractal is a self-similar subset of Euclidean space whose fractal dimension strictly exceeds its topological dimension. Fractals appear the same at different levels, as illustrated in successive magnifications of a Mandelbrot set. Fractals exhibit similar patterns at increasingly small scales called self similarity, also known as expanding symmetry or unfolding symmetry. if the replication is exactly the same at every scale, as in the Menger sponge, the fractal is considered to be affine self-similar. Self-similarity may be found in nature, for example in Romanesco broccoli or in a fern frond. Fractal geometry lies within the mathematical branch of measure theory. Every fractal has an initiator and generator. The initiator represents the first step of the fractal. The generator produces each phase or step of the fractal. A generator is an arranged collection of scaled copies of the initiator. For generating a fractal, a plurality of steps may be performed and for each step, every copy of the initiator is replaced with a scaled copy of the generator, rotating as necessary. A generator may be any geometrical shape that yields optimization when the shape is repeated. A “k” value for the fractal may indicate the amount of granularity of the self-similarity that is propagated in shape of the design from the background portion. The second segmented map fractal 404b of the segmented fractal map 400 shown in FIG. 4 has a “k” value of 2 with respect to its initiator and generator. The production of this second segmented map fractal 404b is shown in FIG. 5, where the example initiator 500 is shown where k=0, the example generator 502 is shown where k=1, and then the second segmented map fractal 404b is shown where k=2. The name “second segmented map fractal 404b” refers to this fractal being present in the segmented fractal map 400 shown in FIG. 4

To perform step 212, the weather station placement program 110a, 110b may include or may access fractal generator software. Numerous commercial and open-source fractal generator software programs are available for accessing by the weather station placement program 110a, 110b or for downloading to be part of the weather station placement program 110a, 110b and that subsequently may be used to generate fractals.

The desired fractal configurations that are generated may be generated on a two-dimensional (2D) surface as a map or as a three-dimensional (3D) surface. A 2D fractal may be sufficient, especially if a variance in height of a landscape is minimal.

At least two fractal configurations may be generated for step 212, but in practice as this step 212 may be performed by software on a computer many more fractal configurations than two may be generated for step 212.

In a step 214 of the weather station placement process 200, the fractal configurations are iteratively matched to the weather forecast performance map of existing weather stations. The weather forecast performance map may be the map that was generated in step 210. The fractal configurations may be those fractal configurations that were generated in step 212. Individual fractals of these fractal configurations may come from a variety of combinations of initiators and generators.

The iterative matching of step 212 may include the weather station placement program 110a, 110b overlaying the generated fractal configurations one at a time onto the weather forecast performance map. Then calculations may be performed by the weather station placement program 110a, 110b to determine how far each weather station point is from a respective nearest node of the fractal. A first optimization score may be generated in step 212 by determining a sum of all the distances between the nodes and the weather station points. Due to the use of the computer and the weather station placement program 110a, 110b, respective first optimization scores may be determined for different positions of a single generated fractal configuration overlaid onto the weather forecast map and then for other fractal configurations overlaid onto the weather forecast performance map. An overlaid position which minimizes the first optimization score may be chosen as a priority overlaid position for one fractal configuration. First optimization scores of the respective priority overlaid positions for a plurality of fractal configurations, e.g., for at least two fractal configurations, may be generated and compared to each other in step 212. The fractal configuration with the overall lowest first optimization score may be chosen as the best match for the weather station map configuration. This chosen fractal configuration may be considered a first fractal and may most closely match a layout of the current locations of the first weather stations at which the weather forecast model had best forecasting accuracy levels.

The different fractal configurations that are iteratively tested may include a single fractal design but with increased or decreased “k” values. A first fractal design with a low “k” value may have a better optimization score than a first fractal design with a high “k” value. The second segmented map fractal 404b of the segmented fractal map 400 shown in FIG. 4 has a “k” value of 2 with respect to its initiator and generator.

In some embodiments, an enhanced optimization score may be determined by incorporating other parameters as alternatives to or in addition to the above-described distance minimization. For this enhanced optimization, a linear model may be generated to determine an enhanced optimization score using the formula: Enhanced optimization score=parameter N*weight X for N parameters.

The iterative matching may be performed for weather forecast performance maps that have been separated to show weather station points corresponding to various accuracy levels of the weather forecast model for predicting weather in the areas around and at those weather stations. Thus, a first fractal may be chosen as a best match for weather stations in highest accuracy levels. A second fractal may be chosen as a best match for weather stations in medium accuracy levels. A third fractal may be chosen as a best match for weather stations in lowest accuracy levels. These different fractals may subsequently be presented on the same map or on different maps.

In some embodiments, nodes of the fractal may be a center, an apex, or a central base point of the generator. The nodes may respectively belong to repeated units of the fractal, e.g., to the smallest of the individual repeated units of the fractal. The type of node may depend on the shape of the initiator and the generator. For example, a repeated triangular shape may have a node at the apex or at the center of the triangle, a repeated square or rectangle shape may have a node at the center, apex, or central base of the square or rectangle, a repeated circle shape may have a node at the center of the circle. In some embodiments, a user may select the node type. The weather station placement program 110a, 110b may have default node types that are used. The distance of weather station points from the node may be made with respect to these specific examples of node types, e.g., the distance from the weather station point to the apex or center of the triangle, or to the center of base central point or apex central point of the square, etc. In some embodiments, the summed minimum distance determinations of the weather station points to the fractal nodes may be performed with respect to any point along the lines of the fractal.

In the first fractal 304a of the first fractal map 300A shown in FIG. 3A, the nodes are at a central point of each triangle of the first fractal 304a. Thus, this triangle-based fractal was chosen as the best suited fractal whose nodes would match the first, second, third, and fourth points 306a, 306b, 306c, and 306d representing weather stations at which the weather forecast model had best forecast performance. In the second fractal 304b of the second fractal map 300B shown in FIG. 3B, the nodes are at an apex of each triangle of the second fractal 304b. Thus, this triangle-based fractal was chosen as the best suited fractal whose nodes would match the fifth, sixth, seventh, and eighth points 312a, 312b, 312c, and 312d representing weather stations at which the weather forecast model had best forecast performance. FIGS. 3A and 3B use the same fractal design but with different node positions within the repeated fractal units of these designs.

Thus, for the first fractal 304a of the first fractal map 300A shown in FIG. 3A, the summed minimum distance determinations of the weather station points to the fractal nodes may be in total an amount equal to the first distance 310. The fourth point 306d is disposed the first distance 310 from the central node 308. The first, second, and third points 306a, 306b, and 306c are each disposed at the other central nodes, so that they have no distance to add to the summed minimum distance determination.

For the second fractal 304b of the second fractal map 300B shown in FIG. 3B, the summed minimum distance determinations of the weather station points to the fractal nodes may be in total an amount equal to the second distance 316. The eighth point 312d is disposed the second distance 316 from the apex node 314. The fifth, sixth, and seventh points 312a, 312b, and 312c are each disposed at the other apex nodes, so that they have no distance to add to the summed minimum distance determination.

As the overlaid map may be generated for a weather forecast performance map with a time-based component, the overlaid map may also indicate this time-based component of the length into the future of the weather prediction.

In some embodiments, the overlaid map may include segmentation of the map regions with a different fractal configuration for one or more of the various map regions. The different fractal configurations may include different initiators and generators as compared to a first fractal for a first map region. The different fractal configurations may also include increased or decreased “k” values for a single type of fractal. The “k” value may, from the background portion, identify how granular the self-similarity (i.e. the shape) of the design propagates. FIG. 4 shows an example of a segmented fractal map 400 which shows an overlaid map with different segmentations of fractals. Specifically, in a northern region of the third land mass 402 shown in the segmented fractal map 400 in FIG. 4 a first segmented map fractal 404a with a triangular basis had nodes which provide a best match for a first group of points representing weather stations at which the weather forecast model had best forecast performance. The first northern point 406a is labeled of this first group of points. In a southern region of the third land mass 402 of the segmented fractal map 400 a second segmented map fractal 404b with lines at ninety degree angles to each other had nodes which provide a best match for a second group of points which also represent weather stations at which the weather forecast model had best forecast performance. The first southern point 406b is labeled of this first group of points. With the first segmented map fractal 404a and the second segmented map fractal 404b on the same map, e.g., on the segmented fractal map 400, the segmented fractal map 400 shows one example of the fractal segmentation principle which is possible for some embodiments of the invention.

In a step 216 of the weather station placement process 200, the overlaid map that includes the matched fractal and the weather forecast performance map is presented. On the presented map, individual nodes of the fractal may inherit parameters of the nearest weather station point. The presentation for step 216 may be a visual presentation that occurs via the display screen 924 shown in FIG. 6 or via a screen of the computer 102. The overlaid map may include the matched first fractal being overlaid onto the weather forecast performance map, e.g., on the map that shows the first weather stations at which the weather forecast model had the best weather forecasting success.

In FIG. 3A, the first fractal map 300A is an example of an overlaid map that may be generated as a part of step 216. In FIG. 3B, the second fractal map 300B is an example of an overlaid map that may be generated as a part of step 216. In FIG. 4, the segmented fractal map 400 is an example of an overlaid map that may be generated as a part of step 216. In FIG. 3A, the first fractal map 300A shows a first land mass 302a on which the first fractal 304a has been overlaid. The first fractal 304a is also overlaid over the first, second, third, and fourth points 306a, 306b, 306c, and 306d representing weather stations at which the weather forecast model had best forecast performance. In FIG. 3B, the second fractal map 300B shows a second land mass 302b on which the second fractal 304b has been overlaid. The second fractal 304b has also been overlaid onto the fifth, sixth, seventh, and eighth points 312a, 312b, 312c, and 312d representing weather stations at which the weather forecast model had best forecast performance. In FIG. 4, the segmented fractal map 400 shows a third land mass 402 on which the first segmented fractal 404a has been overlaid. The first segmented fractal 404a has also been overlaid onto a first group of points (including first northern point 406a) representing weather stations at which the weather forecast model had best forecast performance. The second segmented fractal 404b has also been overlaid onto the third land mass 402 and onto a second group of points (including first southern point 406b) also representing weather stations at which the weather forecast model had best forecast performance.

In a step 218 of the weather station placement process 200, user parameters are received as inputs. The weather station placement program 110a, 110b may in at least some embodiments generate a user parameter graphical user interface (GUI) which may be displayed on the display screen 924 or on a screen of the computer 102. A user may use the keyboard 926, the mouse 928, a touch screen of the computer 102, or some other input device to provide input into the user parameter GUI and to provide parameters which the user desires to control the fractal determination and to affect the weather station placement proposal. The weather station placement program 110a, 110b may via this step 218 receive a unique array of user inputs that help produce a fractal map that works best for requirements of specific users.

The user parameters may include cost, as some weather station types with certain equipment are more expensive than other types. A user may implement cost parameters on a granular level and/or on an aggregate level. For example, the cost parameter may be set on a per weather station basis (granular level) or on a geo-fenced basis (aggregate level). The user parameters may include a weather station density for a number of devices in a specific geo-fenced area. The user parameters may include quality of performance which requires the prediction methods of a weather station in a specific location to be above a predefined threshold from linear regression metrics. The user parameters may include other parameters which may be identified and input as ceilings for the creation of the fractal map.

The user parameter GUI may also provide feedback to the user. Such feedback may be generated if a specific threshold has already been met. This feedback may prompt the user to change one or more of the parameters. Such change may occur, for example, via the user using an input device to provide information via the user parameter GUI. Via this feedback and system prompting, the weather station placement program 110a, 110b may alert a user regarding thresholds and current performance or calculations.

In a step 220 of the weather station placement process 200, weak spots in the existing weather station outlay as compared to the matched fractal configuration are identified. The existing weather station outlay may relate to the current positions of weather stations distributed in an earth region. Identifying the weak spots may include identifying weather stations whose positions need to be modified. As an addition to the iterative matching that is performed in step 214 and to accompanying minimum distance calculations, the weather station placement program 110a, 110b may also calculate one or more position enhancements for the current weather stations. For example, a suggestion may be given where a shift in position of one or more existing weather stations might help improve weather forecasting. Such shift might help to better match one or more existing weather stations to a fractal pattern and/or might help to capture weather variables from a somewhat different position. Such shifting may increase the weather forecast accuracy. In the embodiment of FIG. 3A, the weather station placement program 110a, 110b may identify that shifting the fourth point 306d the first distance 310 to be disposed at the central node 308 may help better measure weather variables in a way that may increase weather forecast accuracy. In the embodiment of FIG. 3B, the weather station placement program 110a, 110b may identify that shifting the eighth point 312d the second distance 316 to be disposed at the apex node 314 may help better measure weather variables in a way that may increase weather forecast accuracy. If the distance of a weather station point from the node is greater than a first threshold that may be preset by the user as a parameter or may be determined by machine learning, then the weather station placement program 110a, 110b may make this suggestion.

The identification of weak spots may occur by the weather station placement program 110a, 110b analyzing the overlaid fractal configuration on the weather forecast accuracy map which includes points corresponding to real-earth positions of the weather stations. These points on the map may be referred to as map points. The weather station placement program 110a, 110b may determine by comparison to stored fractal systems in a fractal library that reducing the total summed distance of weather station points to nodes would increase the weather station forecasting accuracy. Moving some of the locations of the weather stations in the outlay may reduce the total summed distance. The fractal library may store asymptotic totals of total summed distances, whereby at some point decreasing the total summed distance further achieves negligible improvement in weather forecasting (law of diminishing returns). The user may input thresholds for acceptable amount distance from an asymptotic value, so that suggestions for substantially small improvements in weather forecasting accuracy may be avoided. The weak spots and suggestions for remedying the weak spots may be presented to the user via display on the display screen 924 and/or on the screen of the computer 102.

Step 220 may also include the performance of a K-nearest neighbor algorithm “K-NN algorithm” to check for weak spots as compared to the fractal configuration or other fractal configurations in a fractal library stored for the weather station placement program 110a, 110b. As part of this K-NN algorithm, the topological characteristics, e.g., the terrain, of the land in and around the existing weather station outlay may be compared to other topological characteristics for which optimized fractal configurations for weather station outlay have been identified and stored in the fractal library. The topological characteristics of the land and location points of the weather stations may be used as input for performing the K-NN algorithm to match the terrain around or/of locations already having weather stations implemented to other tested weather station system outlays. The K-NN algorithm may include comparing new terrain to existing fractal maps to determine an optimal fractal generator and initiator. The K-NN algorithm may include a supervised classification algorithm where labeled points nearest to new points are used by the machine learning model to classify new points, as the nearest points are said to vote on the classifying of the new points.

As part of step 220, the weather station placement program 110a, 110b may determine if the model indicates that increasing the number of weather stations in an area, i.e., increasing the weather station density in the area, would increase weather forecast accuracy. This area may be within a specified radius from a central point. The weather station placement program 110a, 110b may use the iterations and/or the K-NN algorithm to generate and suggest placement of weather stations within a desired radius of the fractal nodes. The weather station placement program 110a, 110b may identify what allowable distance thresholds exist that minimize distance from the node to the weather station and that maximize capturing of weather variables to maximize weather forecast accuracy. The weather station placement program 110a, Hob may suggest increasing the weather station density up to a point of diminishing returns, where further addition would increase costs and give negligible meaningful/helpful increase in weather measurement that would help weather forecasting. For example, in some instances it may not be an optimal use of resources to have weather stations on both sides in the immediate vicinity of a single house.

In a step 222 of the weather station placement process 200, the weather station placement program 110a, 110b determines whether any new areas that lack weather stations are to be examined. Over time as humans expand and populate more of the physical world, fewer areas will be left at which the weather is not being measured, but such areas still exist. This determination of step 222 may include receiving a map or map data of areas for which weather forecasts are desired. The weather station placement program 110a, 110b may compare the map with the distribution of existing weather stations to determine if new areas exist that lack any weather stations. For example, for the segmented fractal map 400 shown in FIG. 4 the weather station placement program 110a, 110b may analyze and determine that more weather stations in a northwest area of the third land mass 402 would be helpful in obtaining weather measurements that may lead to improved weather forecasting.

A user may also use the data input devices such as the keyboard 926, the mouse 928, or a touch screen of the computer 102 to command the weather station placement program 110a, 110b to perform a fresh analysis for an area that presently has no weather stations. The weather station placement program 110a, 110b may in some embodiments prompt the user with a graphical user interface to ask if such new areas should be analyzed. If the step 222 results in a negative determination, the weather station placement process 200 may skip steps 224 and 226 and proceed to step 228. If the step 222 results in a positive determination, the weather station placement process 200 may proceed to steps 224 and 226 after step 222. The response to the positive determination may include increasing the number of existing weather stations and proposing then adding new stations for the new area.

In a step 224 of the weather station placement process 200, topological input regarding the new area is received. This topological input may be referred to as new topological data, especially if topological data had already been received regarding other areas. The weather station placement program 110a, 110b may perform map analysis machine learning or natural language processing (NLP) to scrape, from text on the map, topological information about the new area from the map itself. The NLP process may include performing optical character recognition on text of the map, if the map text is not delivered in machine-encoded text. The topological information/input may include information about the terrain of the new area. A user may also use the data input devices such as the keyboard 926, the mouse 928, or a touch screen of the computer 102 to input to the weather station placement program 110a, 110b topological information about the new area. The weather station placement program 110a, 110b may in some embodiments prompt the user with a graphical user interface to ask for topological information regarding the new area.

In a step 226 of the weather station placement process 200, a K-NN algorithm is performed to identify a fractal configuration for the new area. The K-nearest neighbor algorithm “K-NN algorithm” may compare the topological information or other input parameters to the topological information associated with fractal configuration or with other fractal configurations in a fractal library stored for the weather station placement program 110a, 110b. The system may use machine learning to propose a fractal configuration for the new area. This identification may help indicate which fractal might be best to fill in some existing space that lacks weather stations as a part of a larger weather station network.

In some embodiments, the map data may be compared with existing fractal maps to determine a second fractal that is best suited for the new geographical area. This comparison may be part of or in alternative to step 226. New topological data that is received regarding the new area may be compared to topological data for existing fractal maps. This comparison may indicate a second fractal, as opposed to the first fractal on the overlaid map presented in step 216, that is best suited for weather stations of the new geographical area. The K-NN algorithm may include a supervised classification algorithm where labeled points nearest to new points are used by the machine learning model to classify new points, as the nearest points are said to vote on the classifying of the new points.

In a step 228 of the weather station placement process 200, weather station types are selected and cycled at each node to deliver optimal output. Those weather station types that are grouped and indexed in step 206 may be analyzed to determine which weather station type if implemented in a location of the examined area would lead to best enhancement of weather forecasting. The weather station placement program 110a, 110b may iteratively examine whether using a weather station with different equipment so that different weather variables may be measured would lead to enhancement of weather forecasting. The weather station placement program 110a, 110b may cycle through various weather station type iterations for the weather station locations to see if the performance of the weather forecast model would be increased. This cycling and selecting may also include analysis of user parameters that were received in step 218, e.g., cost parameters that may affect choice of equipment to be installed.

In a step 230 of the weather station placement process 200, a chosen model is built according to the fractal map. As a prelude to step 230, weather station modifications may be suggested to the user. The weather station modifications may include suggestions for remedying the weak spots that were identified in step 220, may include a proposed fractal configuration for a new area that was determined in step 226, and may include switching of any weather station types as determined in step 228. The proposal may be a result of leveraging clustering algorithms to identify optimal placements of weather stations. As the weather station placement program 110a, 110b may take into account actual topology of an area, proposed placements of weather stations may include some divergence from exact node points of the fractal due to topological interference, inaccessibility, or lack of property rights to place a weather station exactly at the fractal node point. These suggestions may be presented to the user via a display on the display screen 924 or on a screen of the computer 102. The suggestions may be presented in a report with one or more maps that are generated.

The suggestions may include an aggregate score for various models. The aggregate score may include input such as number of devices, quality of measuring/forecasting expected, cost for system, etc. A formula may be Aggregate Score=(#of devices*YY)+(quality*XX)+(cost*ZZ)+ . . . +(Parameter N*Weight N), where YY, XX, and ZZ are weights given to emphasize or deemphasize certain of these parameters. The model with the optimal aggregate score may be selected by the weather station placement program 110a, 110b and/or by the user.

The user may choose a best suggestion or one of the suggestions that are generated. The user and/or associates and/or helpers may manually build out weather stations according to the chosen model. The manual build out may include installing weather equipment at the specified location or locations.

In a step 232 of the weather station placement process 200, weather data is recorded with the built model. The built model may include modifications of positions of existing weather stations and/or modifications of equipment and/or instruments at existing weather locations to modify a type of an existing weather station. Instruments and equipment of the built model may measure and record weather variables. The newly recorded weather data may be transmitted via the communication network 116 to other computers and to the computer 102 and/or to the server 112 which host the weather station placement program 110a, 110b. Step 232 may take hours, days, weeks, months, and/or years to complete, as new weather data is recorded continuously or on a regularly scheduled basis. With the new data, certain portions and steps of the weather station placement process 200 may be repeated to verify that the modification and/or the new fractal design led to improved accuracy for the weather forecast model.

In a step 234 of the weather station placement process 200, the historical corpus is updated with weather patterns, fractal map layouts, and results of the built model. The new weather data that has been recorded in step 232 may be added to the historical corpus for inputting to the weather forecast model. The fractal map layouts that were identified and suggested in previous steps of the weather station placement process 200 may be added into the historical corpus, e.g., as part of a fractal library of the historical corpus which may be accessed or be part of the weather forecast model. This updating may constitute or be part of a feedback mechanism for the fractal-based weather station placement for modifying weather variable measurement to achieve better weather forecasting. This updating of step 234 would facilitate other steps of the weather station placement process 200 being repeated so that the weather station placement program 110a, 110b may in some embodiments continuously observe the existing landscape and look for additional placements of weather stations to improve readings and/or forecasting. For example, steps 202 to 216 may be repeated to enhance understanding of how accurate forecasting for a specific region is with its specific fractal configuration. By repeating and using the feedback mechanism, a fractal library in the weather station placement program 110a, 110b may better indicate which fractal designs for the weather station layouts worked best, e.g., in general or with respect to certain topological conditions. This feedback may be constant or frequently repeated. The weather station placement program 110a, 110b, e.g., the historical corpus and the weather forecast model thereof, may constitute a machine learning model configured to continuously analyze and better understand locations of weather stations in order to improve weather variable measurement and, as a result of that improvement in measurement, weather forecasting. The updated machine learning model is configured to dynamically provide suggestions for the weather station placement design to enhance weather forecasting.

The weather station placement program 110a, 110b constituting machine learning may in some embodiments include outlier digital triangulation. With outlier digital triangulation, the average delta in fractals may be utilized to identify outliers in the weather stations that may be seen on a day to day basis of the actual weather. By following the weather trends (e.g., by receiving regular updates of actual weather data) and fractal shifting, the weather station placement program 110a, 110b may achieve accurate readings for a present time and may be able to identify where weather stations should be based on aggregate changing fractal conditions such as those influenced by climate change. The weather station placement program 110a, 110b constituting machine learning may also be able to interpret outliers in weather events, such that drastic changes in weather station placement may be considered and further confirmation of likelihood of similar weather events may be obtained before making the placement changes.

The weather station placement program 110a, 110b constituting machine learning may in some embodiments include mobile weather station positioning suggestion and detection. The weather station placement program 110a, 110b may be aware of the current and changing state of fractal weather patterns and use these fractal weather patterns as a basis for geographically and dynamically positioning weather stations that are mobile, e.g., temporarily mobile. These mobile weather stations may be positioned in locations optimized by the fractal output. These temporarily mobile weather stations may act as mobile sensors, while the physical weather stations may act as fixed sensors.

It may be appreciated that FIGS. 2, 3A-3B, 4, and 5 provide only illustrations of some embodiments and do not imply any limitations with regard to how different embodiments may be implemented. Many modifications to the depicted embodiment(s), e.g., to a depicted sequence of steps, may be made based on design and implementation requirements.

FIG. 6 is a block diagram 900 of internal and external components of computers depicted in FIG. 1 in accordance with an illustrative embodiment of the present invention. It should be appreciated that FIG. 6 provides only an illustration of one implementation and does not imply any limitations with regard to the environments in which different embodiments may be implemented. Many modifications to the depicted environments may be made based on design and implementation requirements.

Data processing system 902a, 902b, 904a, 904b is representative of any electronic device capable of executing machine-readable program instructions. Data processing system 902a, 902b, 904a, 904b may be representative of a smart phone, a computer system, PDA, or other electronic devices. Examples of computing systems, environments, and/or configurations that may represented by data processing system 902a, 902b, 904a, 904b include, but are not limited to, personal computer systems, server computer systems, thin clients, thick clients, hand-held or laptop devices, multiprocessor systems, microprocessor-based systems, network PCs, minicomputer systems, and distributed cloud computing environments that include any of the above systems or devices.

User client computer 102 and server 112 may include respective sets of internal components 902a, 902b and external components 904a, 904b illustrated in FIG. 6. Each of the sets of internal components 902a, 902b includes one or more processors 906, one or more computer-readable RAMs 908 and one or more computer-readable ROMs 910 on one or more buses 912, and one or more operating systems 914 and one or more computer-readable tangible storage devices 916. The one or more operating systems 914, the software program 108a, and the weather station placement program 110a in client computer 102, the software program 108b and the weather station placement program 110b in server 112, may be stored on one or more computer-readable tangible storage devices 916 for execution by one or more processors 906 via one or more RAMs 908 (which typically include cache memory). In the embodiment illustrated in FIG. 6, each of the computer-readable tangible storage devices 916 is a magnetic disk storage device of an internal hard drive. Alternatively, each of the computer-readable tangible storage devices 916 is a semiconductor storage device such as ROM 910, EPROM, flash memory, or any other computer-readable tangible storage device that can store a computer program and digital information.

Each set of internal components 902a, 902b also includes a R/W drive or interface 918 to read from and write to one or more portable computer-readable tangible storage devices 920 such as a CD-ROM, DVD, memory stick, magnetic tape, magnetic disk, optical disk or semiconductor storage device. A software program, such as the software program 108a, 108b and the weather station placement program 110a, 110b can be stored on one or more of the respective portable computer-readable tangible storage devices 920, read via the respective R/W drive or interface 918 and loaded into the respective hard drive 916.

Each set of internal components 902a, 902b may also include network adapters (or switch port cards) or interfaces 922 such as a TCP/IP adapter cards, wireless wi-fi interface cards, or 3G or 4G wireless interface cards or other wired or wireless communication links. The software program 108a and the weather station placement program 110a in client computer 102, the software program 108b and the weather station placement program 110b in the server 112 can be downloaded from an external computer (e.g., server) via a network (for example, the Internet, a local area network or other, wide area network) and respective network adapters or interfaces 922. From the network adapters (or switch port adaptors) or interfaces 922, the software program 108a, 108b and the weather station placement program 110a in client computer 102 and the weather station placement program 110b in server 112 are loaded into the respective hard drive 916. The network may include copper wires, optical fibers, wireless transmission, routers, firewalls, switches, gateway computers and/or edge servers.

Each of the sets of external components 904a, 904b can include a computer display monitor 924, a keyboard 926, and a computer mouse 928. External components 904a, 904b can also include touch screens, virtual keyboards, touch pads, pointing devices, and other human interface devices. Each of the sets of internal components 902a, 902b also includes device drivers 930 to interface to computer display monitor 924, keyboard 926 and computer mouse 928. The device drivers 930, R/W drive or interface 918 and network adapter or interface 922 include hardware and software (stored in storage device 916 and/or ROM 910).

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

It is understood that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure comprising a network of interconnected nodes.

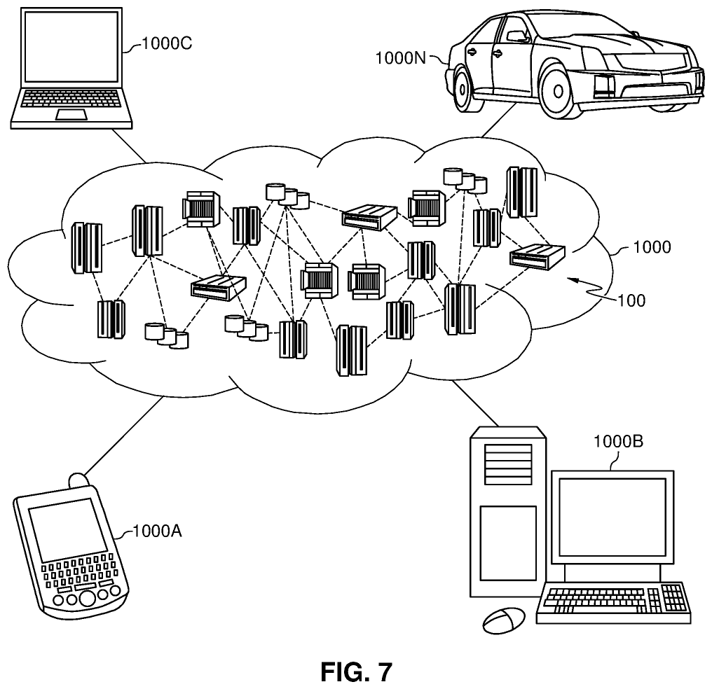

Referring now to FIG. 7, illustrative cloud computing environment 1000 is depicted. As shown, cloud computing environment 1000 comprises one or more cloud computing nodes 100 with which local computing devices used by cloud consumers, such as, for example, personal digital assistant (PDA) or cellular telephone 1000A, desktop computer 1000B, laptop computer 1000C, and/or automobile computer system 1000N may communicate. Nodes 100 may communicate with one another. They may be grouped (not shown) physically or virtually, in one or more networks, such as Private, Community, Public, or Hybrid clouds as described hereinabove, or a combination thereof. This allows cloud computing environment 1000 to offer infrastructure, platforms and/or software as services for which a cloud consumer does not need to maintain resources on a local computing device. It is understood that the types of computing devices 1000A-N shown in FIG. 7 are intended to be illustrative only and that computing nodes 100 and cloud computing environment 1900 can communicate with any type of computerized device over any type of network and/or network addressable connection (e.g., using a web browser).

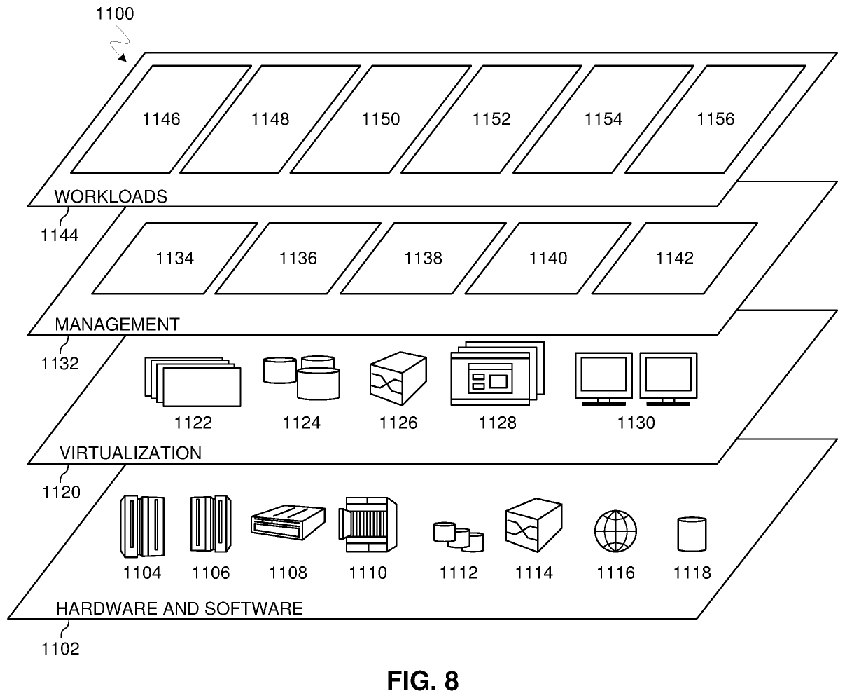

Referring now to FIG. 8, a set of functional abstraction layers 1100 provided by cloud computing environment 1000 is shown. It should be understood in advance that the components, layers, and functions shown in FIG. 7 are intended to be illustrative only and embodiments of the invention are not limited thereto. As depicted, the following layers and corresponding functions are provided:

Hardware and software layer 1102 includes hardware and software components. Examples of hardware components include: mainframes 1104; RISC (Reduced Instruction Set Computer) architecture based servers 1106; servers 1108; blade servers 1110; storage devices 1112; and networks and networking components 1114. In some embodiments, software components include network application server software 1116 and database software 1118.

Virtualization layer 1120 provides an abstraction layer from which the following examples of virtual entities may be provided: virtual servers 1122; virtual storage 1124; virtual networks 1126, including virtual private networks; virtual applications and operating systems 1128; and virtual clients 1130.

In one example, management layer 1132 may provide the functions described below. Resource provisioning 1134 provides dynamic procurement of computing resources and other resources that are utilized to perform tasks within the cloud computing environment. Metering and Pricing 1136 provide cost tracking as resources are utilized within the cloud computing environment, and billing or invoicing for consumption of these resources. In one example, these resources may comprise application software licenses. Security provides identity verification for cloud consumers and tasks, as well as protection for data and other resources. User portal 1138 provides access to the cloud computing environment for consumers and system administrators. Service level management 1140 provides cloud computing resource allocation and management such that required service levels are met. Service Level Agreement (SLA) planning and fulfillment 1142 provide pre-arrangement for, and procurement of, cloud computing resources for which a future requirement is anticipated in accordance with an SLA.

Workloads layer 1144 provides examples of functionality for which the cloud computing environment may be utilized. Examples of workloads and functions which may be provided from this layer include: mapping and navigation 1146; software development and lifecycle management 1148; virtual classroom education delivery 1150; data analytics processing 1152; transaction processing 1154; and weather station placement 1156. A weather station placement program 110a, 110b provides a way to improve design of outlay of weather stations to improve weather variable measurement and, as a result, weather prediction.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises,” “comprising,” “includes,” “including,” “has,” “have,” “having,” “with,” and the like, when used in this specification, specify the presence of stated features, integers, steps, operations, elements, and/or components, but does not preclude the presence or addition of one or more other features, integers, steps, operations, elements, components, and/or groups thereof.

The descriptions of the various embodiments of the present invention have been presented for purposes of illustration but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method for weather station placement design, the method comprising:
receiving weather data measured at weather stations, current location data regarding current locations of the respective weather stations, and weather forecast data generated by a weather forecast model;
determining forecast performance by the weather forecast model by comparing the weather data to the weather forecast data and so that first weather stations where the weather forecast model had best forecast performance are identified;
generating a weather forecast performance map based on the identified first weather stations;
generating fractals;
iteratively matching the fractals to the weather forecast performance map to identify a first fractal of the fractals that most closely matches a layout of the current locations of the first weather stations; and
presenting a first fractal map comprising the first fractal overlaid on the weather forecast performance map.

2. The method of claim 1, further comprising:
receiving map data regarding a new geographical area that lacks weather stations;
comparing the map data with existing fractal maps to determine a second fractal best suited for the new geographical area; and
presenting a second fractal map, wherein the second fractal map comprises the second fractal being overlaid on a second map and comprises points for new weather stations corresponding to nodes of the second fractal.

3. The method of claim 2, wherein the comparing the map data with the existing fractal maps further comprises performing a K-nearest neighbor algorithm.

4. The method of claim 2, further comprising:
receiving new topological data regarding the new geographical area; and
comparing the new topological data with topological data for the existing fractal maps to determine the second fractal best suited for the new geographical area.

5. The method of claim 2, further comprising receiving a cost parameter as input:
wherein the cost parameter is also used to determine the second fractal best suited for the new geographical area.

6. The method of claim 2, further comprising updating a machine learning model with the first fractal map and with the second fractal map, wherein the updated machine learning model is configured to dynamically provide suggestions for the weather station placement design to enhance weather forecasting.

7. The method of claim 1, further comprising:
identifying at least one position enhancement for at least one of the first weather stations; and
presenting the at least one position enhancement.

8. The method of claim 7, wherein the at least one position enhancement is based on a distance between a node of a generator of the first fractal and a map point for a first weather station, wherein the distance exceeds a first threshold.

9. The method of claim 1, wherein the iterative matching comprises determining a respective distance from map points of the first weather stations to nodes of generators of the fractal s.

10. The method of claim 9, wherein the nodes of the generators comprise at least one member selected from the group consisting of a center of the generator, an apex of the generator, or a central base point of the generator.

11. A computer system for weather station placement design, the computer system comprising:
one or more processors, one or more computer-readable memories, one or more computer-readable tangible storage media, and program instructions stored on at least one of the one or more computer-readable tangible storage media for execution by at least one of the one or more processors via at least one of the one or more computer-readable memories, wherein the computer system is capable of performing a method comprising:
receiving weather data measured at weather stations, current location data regarding current locations of the respective weather stations, and weather forecast data generated by a weather forecast model;
determining forecast performance by the weather forecast model by comparing the weather data to the weather forecast data and so that first weather stations where the weather forecast model had best forecast performance are identified;
generating a weather forecast performance map based on the identified first weather stations;
generating fractals;
iteratively matching the fractals to the weather forecast performance map to identify a first fractal of the fractals that most closely matches a layout of the current locations of the first weather stations; and
presenting a first fractal map comprising the first fractal overlaid on the weather forecast performance map.

12. The computer system of claim 11, wherein the method further comprises:
identifying at least one position enhancement for at least one of the first weather stations; and
presenting the at least one position enhancement.

13. The computer system of claim 12, wherein the method further comprises updating a machine learning model with the first fractal map and with the at least one position enhancement, wherein the updated machine learning model is configured to dynamically provide suggestions for the weather station placement design to enhance weather forecasting.

14. The computer system of claim 11, wherein the iterative matching comprises determining a respective distance from map points of the first weather stations to nodes of generators of the fractal s.

15. The computer system of claim 14, wherein the nodes of the generators comprise at least one member selected from the group consisting of a center of the generator, an apex of the generator, or a central base point of the generator.

16. A computer program product for weather station placement design, the computer program product comprising a computer-readable storage medium having program instructions embodied therewith, wherein the program instructions are executable by a computer system to cause the computer system to perform a method comprising:
receiving weather data measured at weather stations, current location data regarding current locations of the respective weather stations, and weather forecast data generated by a weather forecast model;
determining forecast performance by the weather forecast model by comparing the weather data to the weather forecast data and so that first weather stations where the weather forecast model had best forecast performance are identified;
generating a weather forecast performance map based on the identified first weather stations;
generating fractals;
iteratively matching the fractals to the weather forecast performance map to identify a first fractal of the fractals that most closely matches a layout of the current locations of the first weather stations; and
presenting a first fractal map comprising the first fractal overlaid on the weather forecast performance map.

17. The computer program product of claim 16, wherein the method further comprises:
identifying at least one position enhancement for at least one of the first weather stations; and
presenting the at least one position enhancement.

18. The computer program product of claim 17, wherein the method further comprises updating a machine learning model with the first fractal map and with the at least one position enhancement, wherein the updated machine learning model is configured to dynamically provide suggestions for the weather station placement design to enhance weather forecasting.

19. The computer program product of claim 16, wherein the iterative matching comprises determining a respective distance from map points of the first weather stations to nodes of generators of the fractals.

20. The computer program product of claim 19, wherein the nodes of the generators comprise at least one member selected from the group consisting of a center of the generator, an apex of the generator, or a central base point of the generator.
